(19) United States
(12) Patent Application Publication
(10) Pub. No.: US 2026/0074484 A1
(43) Pub. Date: Mar. 12, 2026

(54) SEMICONDUCTOR LIGHT-EMITTING ELEMENT

(71) Applicant: Nuvoton Technology Corporation Japan, Kyoto (JP)

(72) Inventors: Shuichi FUKUDA, Kyoto (JP); Shinji YOSHIDA, Kyoto (JP); Hideo KITAGAWA, Kyoto (JP)

(21) Appl. No.: 19/389,542

(22) Filed: Nov. 14, 2025

Related U.S. Application Data
(63) Continuation-in-part of application No. PCT/JP2024/020448, filed on Jun. 5, 2024.

(30) Foreign Application Priority Data
Jun. 13, 2023 (JP) 2023-097048

(51) Int. Cl. H01S 5/028

(52) U.S. Cl. CPC H01S 5/0282

(57) ABSTRACT

A semiconductor light-emitting element includes a stacked structure including a semiconductor, the stacked structure having a first end face and a second end face facing each other and forming a resonator; and a protective film disposed on the first end face. The protective film includes a first protective film. The first protective film is an aluminum oxide film or an aluminum oxynitride film to which scandium is added.

### CROSS REFERENCE TO RELATED APPLICATIONS

This is a continuation-in-part application of PCT International Application No. PCT/JP2024/020448 filed on Jun. 5, 2024, designating the United States of America, which is based on and claims priority of Japanese Patent Application No. 2023-097048 filed on Jun. 13, 2023. The entire disclosures of the above-identified applications, including the specifications, drawings, and claims are incorporated herein by reference in their entirety.

### FIELD

The present disclosure relates to a semiconductor light-emitting element.

### BACKGROUND

Conventionally, semiconductor light-emitting elements such as semiconductor laser elements have been used in various technical fields, and there is a demand for an increased optical output. It is typically known that a high optical output operation performed by semiconductor light-emitting elements causes an occurrence of a destructive phenomenon called catastrophic optical damage (COD). Since COD mainly occurs on the emission-side end face that is the light exiting face of resonators included in semiconductor light-emitting elements, efforts have been made, for example, to make durable, stable protective films that cover the emission-side end face.

For example, the semiconductor laser element disclosed by Patent Literature (PTL) 1 attempts to increase adhesion to an end face of the protective film by reducing the stress applied to an active layer.

### CITATION LIST

### Patent Literature

PTL 1: Japanese Patent No. 5572919

### SUMMARY

### Technical Problem

In the semiconductor laser element disclosed by PTL 1, a protective film including an aluminum oxide film is disposed on an end face of a resonator. In such a semiconductor laser element, laser light emitted by the semiconductor laser element causes the following two reactions. The first reaction is the oxidation of the end face due to diffusion of oxygen from outside to the inside of the protective film. The second reaction is expansion or contraction of the protective film due to gradual light-induced crystallization of the protective film. In association with the oxidization of the end face that includes a nitride semiconductor, etc., due to the first reaction, an increase in the amount of light absorption (i.e., the amount of produced heat) in the oxidized portion occurs. This likely causes COD to occur. As described above, the semiconductor laser element disclosed by PTL 1 does not have sufficient reliability for a high optical output operation.

In view of the above, the present disclosure provides a highly reliable semiconductor light-emitting element.

### Solution to Problem

In order to provide the above-described semiconductor light-emitting element, one aspect of a semiconductor light-emitting element according to the present disclosure includes: a stacked structure including a semiconductor, the stacked structure having a first end face and a second end face facing each other and forming a resonator; and a protective film disposed on the first end face. In the semiconductor light-emitting element, the protective film includes a first protective film, and the first protective film is an aluminum oxide film or an aluminum oxynitride film to which scandium is added.

### Advantageous Effects

According to the present disclosure, a highly reliable semiconductor light-emitting element can be provided.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a schematic cross-sectional view showing a configuration of a semiconductor light-emitting element according to Embodiment 1.

FIG. 2 is a cross-sectional view showing a configuration of a protective film according to Embodiment 1.

FIG. 3 illustrates graphs showing overviews of relationships between (i) an amount of light-induced crystallization and a driving time and (ii) an amount of oxygen diffusion and the driving time for first protective films according to Embodiment 1 and fifth protective films according to comparative example 1.

FIG. 4 is a transmission-electron-microscope image of a protective film according to comparative example 1.

FIG. 5 is a first transmission-electron-microscope image of the protective film according to Embodiment 1.

FIG. 6 is a second transmission-electron-microscope image of the protective film according to Embodiment 1.

FIG. 7 is a schematic diagram illustrating light-induced crystallization and oxygen diffusion in a fifth protective film according to comparative example 1.

FIG. 8 is a schematic diagram illustrating light-induced crystallization and oxygen diffusion in a first protective film according to Embodiment 1.

FIG. 9 is a graph showing a relationship between an optical output degradation rate and an aging time for each of semiconductor light-emitting elements according to Embodiment 1 and comparative examples 1 through 3.

FIG. 10 is a graph showing a relationship between a rate of change in a threshold current (Ith) for laser oscillation and an aging time for each of the semiconductor light-emitting elements according to Embodiment 1 and comparative examples 1 through 3.

FIG. 11 is a graph showing a relationship between a rate of change in slope efficiency (Se) and an aging time for each of the semiconductor light-emitting elements according to Embodiment 1 and comparative examples 1 through 3.

FIG. 12 is a schematic diagram illustrating the shape of a surface of a fifth protective film according to comparative example 1.

FIG. 13 is a schematic diagram illustrating the shape of a surface of a first protective film according to Embodiment 1.

FIG. 14 is a cross-sectional view showing a configuration of a protective film according to Embodiment 2.

FIG. 15 is a cross-sectional view showing a configuration of a protective film according to Embodiment 3.

FIG. 16 is a cross-sectional view showing a configuration of a protective film according to Embodiment 4.

FIG. 17 is a cross-sectional view showing a configuration of a protective film according to Embodiment 5.

FIG. 18 is a cross-sectional view showing a configuration of a protective film according to Embodiment 6.

FIG. 19 is a cross-sectional view showing a configuration of a protective film according to Embodiment 7.

FIG. 20 is a cross-sectional view showing a configuration of a protective film according to Embodiment 8.

### DESCRIPTION OF EMBODIMENTS

Hereinafter, embodiments according to the present disclosure will be described with reference to the drawings. Note that the embodiments described below each show a specific example of the present disclosure. The numerical values, shapes, materials, elements, the arrangement, connection, and the like of the elements in the following embodiments are mere examples, and therefore do not intend to limit the present disclosure.

Moreover, the drawings each are a schematic diagram, and do not necessarily provide strictly accurate illustration. Accordingly, the drawings do not necessarily coincide with each other in terms of scales and the like. Throughout the drawings, the same reference sign is given to substantially the same element, and redundant description is omitted or simplified.

Moreover, in the present specification, the terms “above/upper” and “below/lower” do not refer to the vertically upward direction and vertically downward direction in terms of absolute spatial recognition, but are used as terms defined by relative positional relationships based on the stacked order in a stacked configuration. In addition, the terms “above/upper” and “below/lower” are applied not only when two elements are disposed spaced apart with another element interposed therebetween, but also when the two elements are disposed in contact with each other.

### Embodiment 1

A semiconductor light-emitting element according to Embodiment 1 will be described.

### [1-1. Overall Configuration]

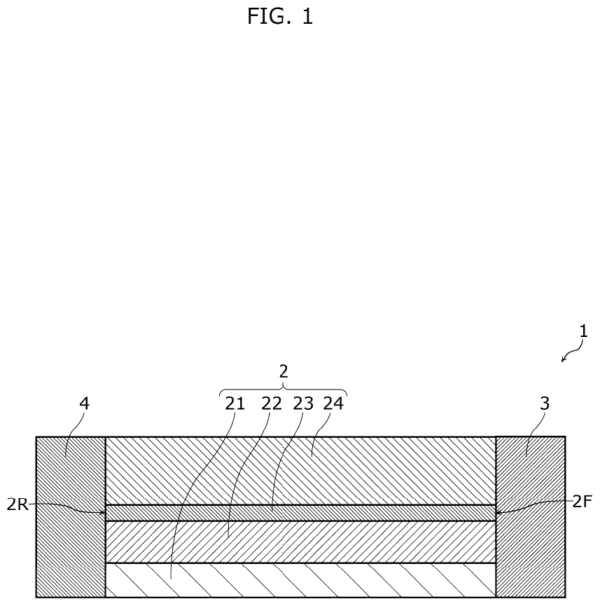

An overall configuration of the semiconductor light-emitting element according to the present embodiment will be described with reference to FIG. 1. FIG. 1 is a schematic cross-sectional view showing a configuration of semiconductor light-emitting element 1 according to the present embodiment. FIG. 1 shows a cross-section that is parallel to (i) the resonance direction of light that semiconductor light-emitting element 1 emits and (ii) the stacked direction of stacked structure 2.

Semiconductor light-emitting element 1 according to the present embodiment is a semiconductor element that emits light. In the present embodiment, semiconductor light-emitting element 1 includes a nitride semiconductor, and is an end-face light emission-type nitride semiconductor laser element that emits laser light in the ultraviolet range. As illustrated in FIG. 1, semiconductor light-emitting element 1 according to the present embodiment includes stacked structure 2 and protective films 3 and 4.

Stacked structure 2 includes a semiconductor, and has first end face 2F and second end face 2R that face each other and form a resonator. In the present embodiment, stacked structure 2 includes a nitride semiconductor. First end face 2F and second end face 2R are faces located at respective ends in the resonance direction (the horizontal direction of FIG. 1) of light that semiconductor light-emitting element 1 emits. The resonance direction is a direction perpendicular to the stacked direction (the up-down direction of FIG. 1) of layers included in stacked structure 2. First end face 2F is the front-side end face from which light from semiconductor light-emitting element 1 is exited. First end face 2F is provided with protective film 3. Second end face 2R is the rear-side end face that reflects light from semiconductor light-emitting element 1. Second end face 2R is provided with protective film 4. In the present embodiment, stacked structure 2 includes substrate 21, first semiconductor layer 22, active layer 23, and second semiconductor layer 24.

Substrate 21 is a plate-like member that serves as the base of stacked structure 2. In the present embodiment, substrate 21 is an n-type GaN substrate having a (0001) plane. Moreover, first end face 2F and second end face 2R are M-planes.

First semiconductor layer 22 is disposed above substrate 21, and includes a first conductivity type semiconductor layer. In the present embodiment, the first conductivity type is the n type, and first semiconductor layer 22 includes an n-side cladding layer including an n-type nitride semiconductor. Note that first semiconductor layer 22 may include an n-type or undoped semiconductor layer, other than the n-side cladding layer.

Active layer 23 is disposed above first semiconductor layer 22, and emits light. In the present embodiment, active layer 23 is a quantum well active layer including a plurality of barrier layers and one or more well layers. Note that active layer 23 may include a first light-guiding layer having the average refractive index greater than the average refractive index of first semiconductor layer 22 and a second light-guiding layer having the average refractive index greater than the average refractive index of second semiconductor layer 24.

Second semiconductor layer 24 is disposed above active layer 23, and includes a second conductivity type semiconductor layer. The second conductivity type is a conductivity type different from the first conductivity type. In the present embodiment, the second conductivity type is the p type, and second semiconductor layer 24 includes a p-side cladding layer including a p-type nitride semiconductor. Note that second semiconductor layer 24 may include a p-type or undoped semiconductor layer, other than the p-side cladding layer.

Note that stacked structure 2 may be provided with electrodes (not illustrated). More specifically, the electrodes may be provided on (i) the bottom surface of substrate 21 (specifically, out of the two principal surfaces of substrate 21, the principal surface on the reverse side of the principal surface on which first semiconductor layer 22 is stacked) and (ii) the upper surface of second semiconductor layer 24 (specifically, out of the two principal surfaces of second semiconductor layer 24, the principal surface on the reverse side of the principal surface that is in contact with active layer 23).

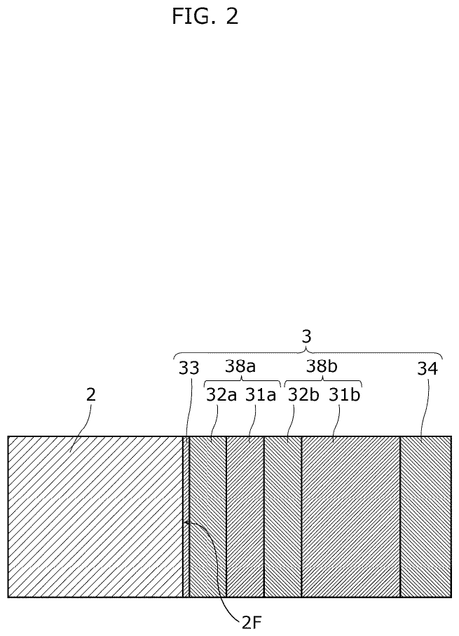

Protective film 3 is disposed on first end face 2F. Hereinafter, protective film 3 will be described with reference to FIG. 2. FIG. 2 is a cross-sectional view showing a configuration of protective film 3 according to the present embodiment. FIG. 2 also shows stacked structure 2. FIG. 2 shows a cross-section that is parallel to (i) the resonance direction of light that semiconductor light-emitting element 1 emits and (ii) the stacked direction of stacked structure 2.

Protective film 3 includes at least one of a first protective film or a second protective film. As illustrated in FIG. 2, protective film 3 includes first protective films 31a and 31b. In addition, protective film 3 includes second protective films 32a and 32b. In the present embodiment, protective film 3 further includes third protective film 33 and fourth protective film 34. As illustrated in FIG. 2, all of the films included in protective film 3 are stacked on first end face 2F.

First protective films 31a and 31b each are an aluminum (Al) oxide film or an aluminum oxynitride film to which scandium (Sc) is added. In the present embodiment, first protective films 31a and 31b each are a scandium-added Al₂O₃ (Al₂O₃:Sc) film. The concentration of scandium added to first protective films 31a and 31b is greater than 0 atomic % (hereinafter, indicated as at %) and less than or equal to 10 at %. The concentration of scandium added to first protective films 31a and 31b may be less than or equal to 7 at %, may be less than or equal to 5 at %, may be less than or equal to 3 at %, or may be less than or equal to 1 at %. Moreover, the concentration of scandium added to first protective films 31a and 31b may be greater than or equal to 0.1 at %. In the present embodiment, the concentration of scandium added to first protective films 31a and 31b is 0.2 at %. In the present embodiment, first protective films 31a and 31b are produced based on the design values of a composition ratio (at %), Al:O:Sc=39.8:60:0.2. Note that the composition ratio of first protective film 31a may be different from the composition ratio of first protective film 31b. The film thickness of first protective film 31a is 12 nm and the film thickness of first protective film 31b is 152 nm. First protective films 31a and 31b each are amorphous or amorphous including a crystalline phase, but may be crystalline.

As illustrated in FIG. 2, second protective film 32a is disposed between first end face 2F and first protective film 31a. Second protective film 32b is disposed between first end face 2F and first protective film 31b. Second protective film 32a is in contact with first protective film 31a, and second protective film 32b is in contact with first protective film 31b. Stated differently, protective film 3 includes stacked films 38a and 38b, and each of stacked films 38a and 38b includes a first protective film and a second protective film that is in contact with the foregoing first protective film. More specifically, stacked film 38a includes first protective film 31a and second protective film 32a that is in contact with first protective film 31a, and stacked film 38b includes first protective film 31b and second protective film 32b that is in contact with first protective film 31b. Note that in the present embodiment, protective film 3 includes two stacked films 38a and 38b, but protective film 3 may include a single stacked film or three or more stacked films.

Second protective films 32a and 32b each are a crystalline film including an aluminum nitride or an aluminum oxynitride. In the present embodiment, second protective films 32a and 32b each are a scandium-added AlON (AlON:Sc) film. The concentration of scandium added to second protective films 32a and 32b is greater than 0 at % and less than or equal to 10 at %. The concentration of scandium added to second protective films 32a and 32b may be less than or equal to 7 at %, may be less than or equal to 5 at %, may be less than or equal to 3 at %, or may be less than or equal to 1 at %. Moreover, the concentration of scandium added to second protective films 32a and 32b may be greater than or equal to 0.1 at %. In the present embodiment, the concentration of scandium added to second protective films 32a and 32b is 0.3 at %. In the present embodiment, second protective films 32a and 32b are produced based on the design values of a composition ratio (at %), Al:O:N:Sc=49.7:12:38:0.3. Note that the composition ratio of second protective film 32a may be different from the composition ratio of second protective film 32b. The film thickness of second protective film 32a is 20 nm and the film thickness of second protective film 32b is 10 nm. Second protective films 32a and 32b each have a polycrystalline structure including at least one of hexagonal crystals or cubic crystals. Here, the cubic crystal indicates a cubic crystal in a narrow definition, not including crystals having the perovskite structure. In the present embodiment, second protective films 32a and 32b each are a hexagonal crystal in the m-axis orientation relative to first end face 2F. The direction perpendicular to first end face 2F agrees with the m-axis direction of second protective films 32a and 32b. Note that in the present embodiment, second protective films 32a and 32b each are a hexagonal crystal in the m-axis orientation, but the orientation characteristic of second protective films 32a and 32b are not limited thereto. For example, the orientation characteristic of second protective films 32a and 32b may be the c-axis orientation, the m+c mixed orientation (i.e., the orientation characteristic in which the m-axis orientation and the c-axis orientation are mixed), or a diagonal orientation.

Third protective film 33 is in contact with first end face 2F. Third protective film 33 is disposed between first end face 2F and second protective film 32a. Third protective film 33 is a silicon nitride film or a silicon oxynitride film. In the present embodiment, third protective film 33 is a SiN film having a film thickness of 0.5 nm. In the present embodiment, third protective film 33 is produced based on the design values of a composition ratio (at %), Si:N=42.9:57.1. Third protective film 33 is amorphous.

Fourth protective film 34 is a silicon oxide film. Protective film 34 is disposed at a position farther from first end face 2F than the positions at which first protective films 31a and 31b are disposed. Stated differently, first protective films 31a and 31b are disposed between first end face 2F and fourth protective film 34. First protective film 31b is in contact with fourth protective film 34. In the present embodiment, fourth protective film 34 is a SiO₂ film having a film thickness of 54 nm. In the present embodiment, fourth protective film 34 is produced based on the design values of a composition ratio (at %), Si:O=33.3:66.7. Fourth protective film 34 is amorphous.

Protective film 4 is disposed on second end face 2R. In the similar manner as protective film 3, protective film 4 may include a first protective film that is a scandium-added aluminum oxide film or a scandium-added aluminum oxynitride film. Moreover, protective film 4 may include a protective film having the composition the same as the composition of at least one of second protective films 32a and 32b, third protective film 33, or fourth protective film 34. The reflectance of second end face 2R on which protective film 4 is disposed is greater than the reflectance of first end face 2F on which protective film 3 is disposed.

### [1-2. Advantageous Effects]

Advantageous effects produced by semiconductor light-emitting element 1 according to the present embodiment will be described in comparison to a semiconductor light-emitting element according to comparative example 1. The semiconductor light-emitting element according to comparative example 1 agrees with semiconductor light-emitting element 1 according to the present embodiment except for the following points: (i) the use of fifth protective films 931a and 931b that include Al₂O₃ without an addition of scandium, instead of first protective films 31a and 31b included in protective film 3 and (ii) the use of sixth protective films 932a and 932b that include AlON without an addition of scandium, instead of second protective films 32a and 32b.

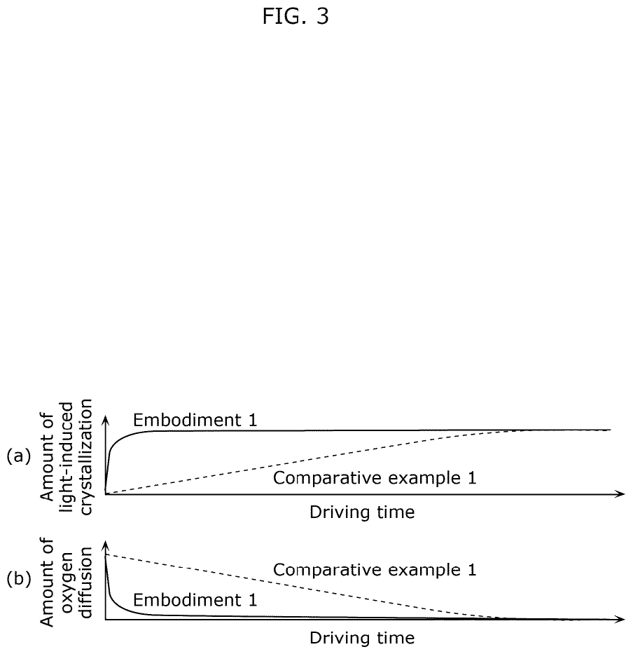

The amount of light-induced crystallization and the amount of oxygen diffusion of first protective films 31a and 31b according to the present embodiment and fifth protective films 931a and 931b according to comparative example 1 will be described with reference to FIG. 3. FIG. 3 illustrates graphs showing overviews of relationships between (i) an amount of light-induced crystallization and a driving time during which semiconductor light-emitting element 1 is driven and (ii) an amount of oxygen diffusion and the driving time for first protective films 31a and 31b according to the present embodiment and fifth protective films 931a and 931b according to comparative example 1. Here, the driving time is a time during which each of semiconductor light-emitting element 1 according to the present embodiment and the semiconductor light-emitting element according to the comparative example emits light by supplying electric currents to semiconductor light-emitting element 1 according to the present embodiment and the semiconductor light-emitting element according to the comparative example. Graph (a) of FIG. 3 shows the relationship between the amount of light-induced crystallization and driving time and graph (b) of FIG. 3 shows the relationship between the amount of oxygen diffusion and the driving time. In first protective films 31a and 31b according to the present embodiment and fifth protective films 931a and 931b according to comparative example 1, light-induced crystallization and oxygen diffusion occur with passage of driving time. The light-induced crystallization is a phenomenon in which an amorphous portion is crystallized due to light emitted by each semiconductor light-emitting element. The oxygen diffusion is a phenomenon in which oxygen present outside each protective film is absorbed and diffused within the protective film. Note that oxygen atoms bonded with aluminum atoms in Al₂O₃ included in each first protective film and each fifth protective film do not diffuse.

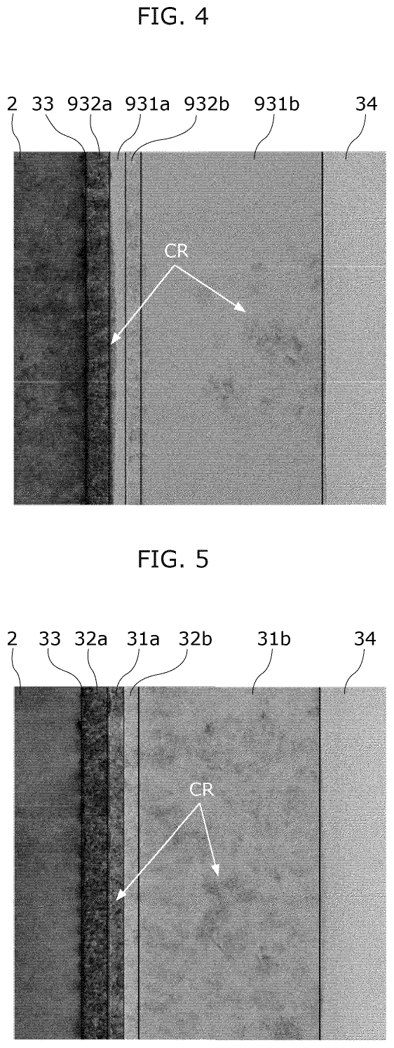

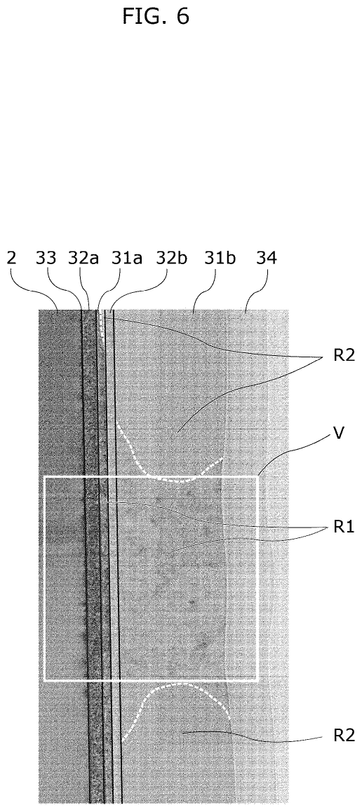

As shown by graph (a) of FIG. 3, light-induced crystallization quickly proceeds in first protective films 31a and 31b according to the present embodiment as compared to fifth protective films 931a and 931b according to comparative example 1. The above-described light-induced crystallization will be described with reference to FIG. 4 through FIG. 6. FIG. 4 is a transmission-electron-microscope (TEM) image of a protective film according to comparative example 1. FIG. 5 and FIG. 6 are a first TEM image of protective film 3 according to the present embodiment and a second TEM image of protective film 3 according to the present embodiment, respectively. FIG. 5 is an enlarged TEM image capturing the inside of square frame V shown in FIG. 6. In FIG. 6, the white dashed lines show the boundaries between internal region R1 and external regions R2 in first protective films 31a and 31b. FIG. 4 through FIG. 6 each illustrate the state of each protective film after conducting an aging test in each semiconductor light-emitting element. In the aging test, each semiconductor light-emitting element was caused to emit continuous wave (CW) laser light of 1.4 W for 1000 hours. The black portions in fifth protective films 931a and 931b shown in FIG. 4 and first protective films 31a and 31b shown in FIG. 5 are light-induced crystallization regions CR. As illustrated in FIG. 4, a region in the vicinity of the interface between fifth protective film 931a and sixth protective film 932a and some regions of fifth protective film 931b are crystallized due to light. As illustrated in FIG. 5 and FIG. 6, a region indicated as internal region R1, that is a wide range encompassing first protective film 31a and first protective film 31b, is crystallized due to light. As described, the amount of light-induced crystallization found after the aging test is greater in first protective films 31a and 31b according to the present embodiment as compared to fifth protective films 931a and 931b according to comparative example 1. As illustrated in FIG. 6, this light-induced crystallization occurs in internal region R1 that includes mainly a region (optical path) through which light emitted by each semiconductor light-emitting element propagates and the vicinity thereof. Stated differently, out of first protective films 31a and 31b, internal region R1 including the optical path is crystallized due to light and external regions R2 outside internal region R1 are not crystallized due to light and are kept amorphous.

As described above, protective film 3 includes light-induced crystallization region CR that has been crystallized due to light. Light-induced crystallization region CR includes at least a portion of a region through which light emitted by semiconductor light-emitting element 1 propagates. In a direction perpendicular to the propagation direction of the light, a dimension of light-induced crystallization region CR in first protective film 31b takes on a minimum value at a position between both interfaces of first protective film 31b.

It is estimated that the refractive index of internal region R1 of first protective films 31a and 31b increases along with such light-induced crystallization. Note that no light-induced crystallization was found in the protective films after the aging test, other than first protective films 31a and 31b.

Note that in FIG. 6, first protective film 31a has a wider light-induced crystallization region CR as compared to first protective film 31b. Stated differently, light-induced crystallization in first protective film 31a has occurred up to a region farther away from the optical path than the light-crystallization occurred in first protective film 31b.

As described, protective film 3 includes first protective film 31a as one example of an inner protective film that is disposed between first end face 2F and second protective film 32. The inner protective film is an aluminum oxide film or an aluminum oxynitride film to which scandium is added. Protective film 3 includes light-induced crystallization region CR including at least a portion of a region through which light emitted by semiconductor light-emitting element 1 propagates. In a direction perpendicular to the propagation direction of the light, a dimension of light-induced crystallization region CR in the inner protective film is greater than a dimension of light-induced crystallization region CR in first protective film 31b.

Both the light-induced crystallization and oxygen diffusion are phenomena that occur due to each protective film being irradiated with light and are conflicting phenomena. For this reason, as shown by graph (b) of FIG. 3, the oxygen diffusion is inhibited more in first protective films 31a and 31b that are speedily crystallized due to light than in fifth protective films 931a and 931b.

Such a mechanism for a quick occurrence of light-induced crystallization in first protective films 31a and 31b according to the present embodiment as described above is not yet unraveled at the present time; however, it is speculated that the addition of scandium could lead to the formation of atomic-level spaces (vacancies) that are used for movement of atoms and are necessary for an occurrence of light-induced crystallization.

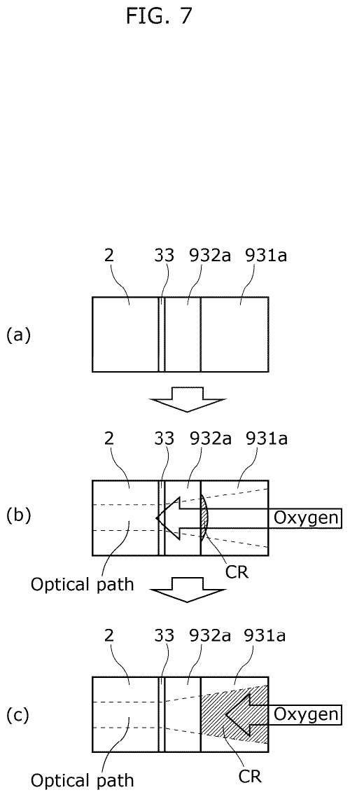

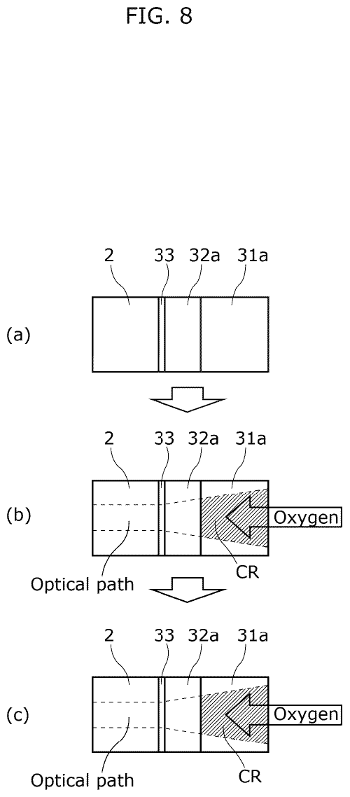

Moreover, the light-induced crystallization regions of first protective films 31a and 31b produce an advantageous effect of inhibiting the oxygen diffusion. This advantageous effect will be described with reference to FIG. 7 and FIG. 8. FIG. 7 and FIG. 8 are a schematic diagram illustrating light-induced crystallization and oxygen diffusion in fifth protective film 931a according to comparative example 1 and a schematic diagram illustrating light-induced crystallization and oxygen diffusion in first protective film 31a according to the present embodiment, respectively. Each of FIG. 7 and FIG. 8 includes schematic diagrams (a), (b), and (c) as follows: schematic diagram (a) illustrates each of protective films immediately after each protective film is formed; schematic diagram (b) illustrates the states of light-induced crystallization and oxygen diffusion in each protective film after an elapse of a relatively short time (e.g., 500 hours) after the driving of the semiconductor light-emitting element is started, and schematic diagram (c) illustrates the states of the light-induced crystallization and oxygen diffusion in each protective film after an elapse of a long time (e.g., 5000 hours) after the driving of the semiconductor light-emitting element is started.

As illustrated in schematic diagram (a) of FIG. 7 and schematic diagram (a) FIG. 8, there is no occurrence of light-induced crystallization or oxygen diffusion in fifth protective film 931a and first protective film 31a immediately after the film formation, since fifth protective film 931a and first protective film 31a are not irradiated with light. As illustrated in schematic diagram (b) of FIG. 7, in the semiconductor light-emitting element according to comparative example 1, a long time (e.g., 5000 hours) is required until fifth protective film 931a is crystallized due to light after the driving is started, since the oxygen diffusion prevails out of the oxygen diffusion and light-induced crystallization in fifth protective film 931a after the driving is started. A region that has been crystallized due to light in fifth protective film 931a has an effect of inhibiting the oxygen diffusion; however, since the light-induced crystallization takes a long time, the oxygen diffused in fifth protective film 931a reaches stacked structure 2 before the entirety of the optical path of fifth protective film 931a is crystallized due to light. Because of this, the nitride semiconductor in stacked structure 2 is oxidized, thereby increasing the light absorption in stacked structure 2. For this reason, COD is likely to occur in the semiconductor light-emitting element according to comparative example 1.

Moreover, since the entirety of the optical path of fifth protective film 931a is crystallized due to light in the state shown in schematic diagram (c) of FIG. 7, the oxygen diffused in fifth protective film 931a can be inhibited from reaching stacked structure 2. In other words, further acceleration in characteristic degradation due to the oxygen diffusion can be inhibited.

Meanwhile, in first protective film 31a according to the present embodiment, the light-induced crystallization prevails out of the oxygen diffusion and light-induced crystallization in first protective film 31a after the driving is started. Accordingly, first protective film 31a is speedily crystallized due to light (e.g., 100 hours). Consequently, as illustrated in schematic diagram (b) of FIG. 8, since first protective film 31a is crystallized due to light, the oxygen diffusion is inhibited in the region that is crystallized due to light. With this, oxygen is inhibited from reaching stacked structure 2. As described, since oxidation of the nitride semiconductor in stacked structure 2 according to the present embodiment can be inhibited, light absorption in stacked structure 2 can therefore be inhibited. From the above, an occurrence of COD in semiconductor light-emitting element 1 can be inhibited.

In addition, as illustrated in schematic diagram (c) of FIG. 8, since oxygen diffused in first protective film 31a can be inhibited from reaching stacked structure 2 even though the driving continues for a long time, the acceleration in characteristic degradation can be inhibited.

As has been described above, semiconductor light-emitting element 1 according to the present embodiment can increase the reliability as compared to the semiconductor light-emitting element according to comparative example 1 by including first protective films 31a and 31b that are scandium-added aluminum oxide films. Note that although the scandium-added aluminum oxide films have been used as first protective films 31a and 31b in the present embodiment, the same advantageous effects can also be obtained using scandium-added aluminum oxynitride films.

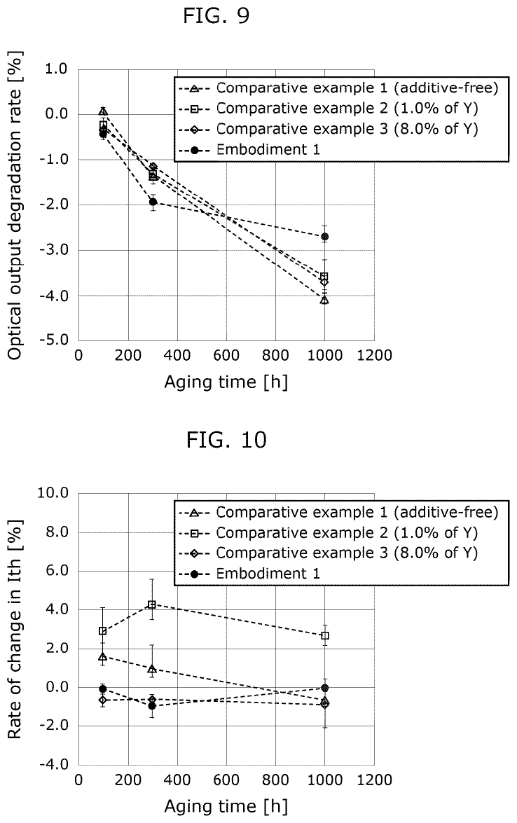

Here, the test result of each of semiconductor light-emitting element 1 according to the present embodiment and the semiconductor light-emitting elements according to comparative example 1 through comparative example 3 will be described with reference to FIG. 9 through FIG. 11. The semiconductor light-emitting elements according to comparative examples 2 and 3 agree with semiconductor light-emitting element 1 according to the present embodiment except for the following points: (i) the use of seventh protective films including yttrium (Y)-added Al₂O₃ (Al₂O₃:Y) instead of first protective films 31a and 31b included in protective film 3 of semiconductor light-emitting element 1 according to the present embodiment and (ii) the use of eighth protective films including yttrium-added AlON (AlON:Y) instead of second protective films 32a and 32b. The concentration of yttrium in the seventh protective films according to comparative example 2 and the concentration of yttrium in the seventh protective films according to comparative example 3 are 1.0% and 8.0%, respectively. Moreover, the concentration of yttrium in the eighth protective films according to comparative example 2 and the concentration of yttrium in the eighth protective films according to comparative example 3 are 1.0% and 8.0%, respectively.

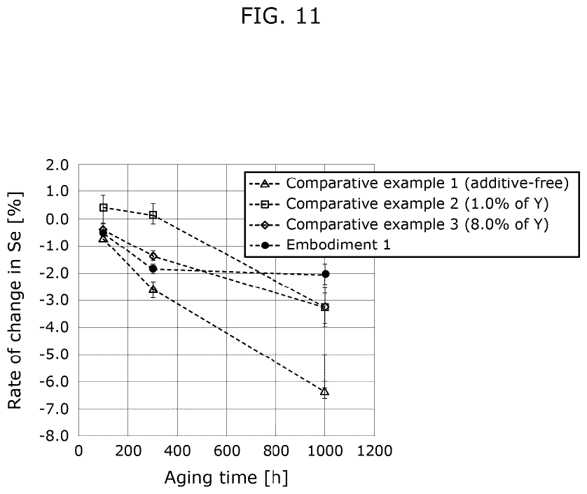

FIG. 9 is a graph showing a relationship between an optical output degradation rate and an aging time for each of the semiconductor light-emitting elements according to the present embodiment and comparative examples 1 through 3. The optical output degradation rate [%] is defined by (P1−P0)×100/P0, where P0 denotes the optical output before the aging test is started (i.e., at aging time 0) and P1 denotes the optical output after the aging test is started. FIG. 10 is a graph showing a relationship between a rate of change in the threshold current (Ith) for laser oscillation and an aging time for each of the semiconductor light-emitting elements according to the present embodiment and comparative examples 1 through 3. The rate of change in Ith [%] is defined by (Ith1−Ith0)×100/Ith0, where Ith0 denotes the threshold current for laser oscillation before the aging test is started and Ith1 denotes the threshold current for laser oscillation after the aging test is started. FIG. 11 is a graph showing a relationship between a rate of change in the slope efficiency (Se) and an aging time for each of the semiconductor light-emitting elements according to the present embodiment and comparative examples 1 through 3. The rate of change in Se [%] is defined by (Se1−Se0)×100/Se0, where Se0 denotes the slope efficiency before the aging test is started and Se1 denotes the slope efficiency after the aging test is started.

As illustrated in FIG. 9, the optical output degradation rate of semiconductor light-emitting element 1 according to the present embodiment after 300 hours of aging is greater than the optical output degradation rate of each of the semiconductor light-emitting elements according to comparative examples 1 through 3, but the optical output degradation rate of semiconductor light-emitting element 1 according to the present embodiment after 1000 hours of aging is less than the optical output degradation rate of each of the semiconductor light-emitting elements according to comparative examples 1 through 3. Moreover, as illustrated in FIG. 10, the threshold for laser oscillation for semiconductor light-emitting element 1 according to the present embodiment hardly changes although aged for 1000 hours. In addition, as illustrated in FIG. 11, the rate of change in Se of semiconductor light-emitting element 1 according to the present embodiment after 300 hours of aging is greater than the rate of change in Se of each of the semiconductor light-emitting elements according to comparative examples 2 and 3, but the rate of change in Se of semiconductor light-emitting element 1 according to the present embodiment after 1000 hours of aging is less than the rate of change in Se of each of the semiconductor light-emitting elements according to comparative examples 1 through 3.

As has been described above, the present embodiment can achieve highly reliable semiconductor light-emitting element 1 that can inhibit degradation due to aging.

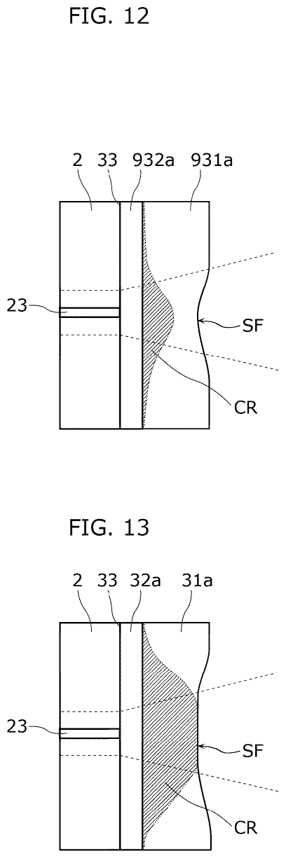

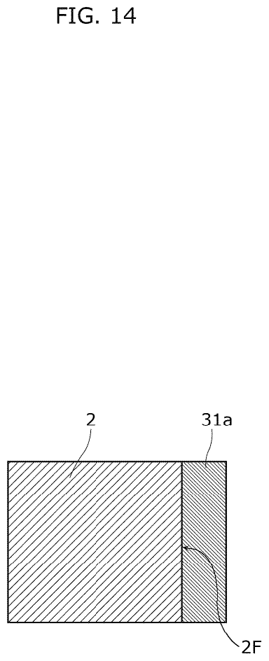

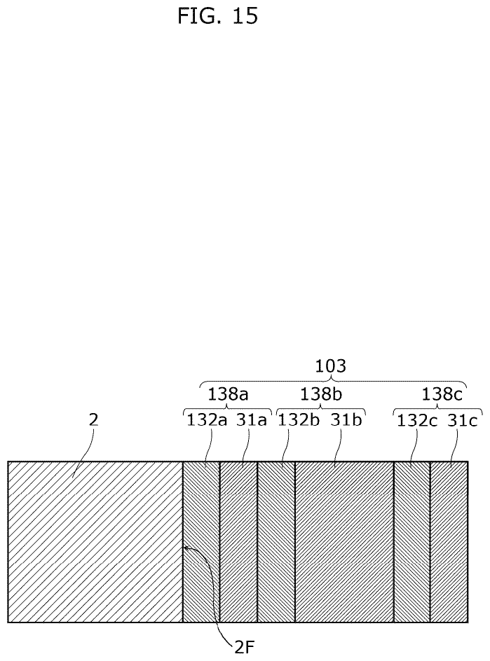

Moreover, semiconductor light-emitting element 1 according to the present embodiment can improve a far field pattern (FFP) of emitted light (laser light). With reference to FIG. 12 and FIG. 13, the above-mentioned advantageous effect will be described in comparison to comparative example 1. FIG. 12 and FIG. 13 are a schematic diagram illustrating the shape of surface SF of fifth protective film 931a according to comparative example 1 and a schematic diagram illustrating the shape of surface SF of first protective film 31a according to the present embodiment, respectively. FIG. 12 and FIG. 13 also show stacked structure 2, third protective film 33, and second protective films 932a and 32a. The dashed lines shown in FIG. 12 and FIG. 13 indicate the outer edges of optical paths.

As illustrated in FIG. 12, since the light-induced crystallization proceeds relatively slowly in fifth protective film 931a according to comparative example 1 (see light-induced crystallization region CR shown in FIG. 12), the change in the film thickness inside the optical path caused along with the light-induced crystallization is uneven. Stated differently, the evenness of surface SF of fifth protective film 931a is reduced. For this reason, instabilities of FFP resulting from the change in the film thickness of fifth protective film 931a occur in the semiconductor light-emitting element according to comparative example 1.

Whereas in first protective film 31a according to the present embodiment, the film thickness of first protective film 31a inside the optical path is approximately even as illustrated in FIG. 13 since the light-induced crystallization speedily proceeds (see light-induced crystallization region CR shown in FIG. 13). Stated differently, a reduction in the evenness of surface SF of first protective film 31a can be inhibited. Therefore, instabilities of FFP can be inhibited in semiconductor light-emitting element 1 according to the present embodiment. Stated differently, FFP can be stabilized in semiconductor light-emitting element 1 according to the present embodiment.

First protective films 31a and 31b may be amorphous or amorphous including a crystalline phase.

With this, energy applied to stacked structure 2 during the film formation can be reduced as compared to forming crystalline protective films as first protective films 31a and 31b. Therefore, damage to stacked structure 2 during the film formation of first protective films 31a and 31b can be inhibited. In addition, damage to second protective film 32a and third protective film 33 can be inhibited at the same time. With this, the reliability of semiconductor light-emitting element 1 can be further increased.

The concentration of scandium added to first protective films 31a and 31b may be less than or equal to 10 at %.

With this, the light-induced crystallization in first protective films 31a and 31b can be further promoted.

Protective film 3 may include second protective film 32a to be disposed between first end face 2F and first protective film 31a, and second protective film 32a may be a crystalline film including an aluminum nitride or an aluminum oxynitride. Protective film 3 according to the present embodiment may include second protective film 32b to be disposed between first end face 2F and first protective film 31b, and second protective film 32b may be a crystalline film including an aluminum nitride or an aluminum oxynitride.

The disposition of each of the above-described second protective films between first end face 2F and each of the first protective films could cause these second protective films to (i) promote the light-induced crystallization in the first protective films or (ii) trap oxygen. With this, oxygen diffusion in each of the first protective films can be further inhibited, and thus the oxidation of stacked structure 2 can be further inhibited. Therefore, the reliability of semiconductor light-emitting element 1 can be increased even more.

In addition, the disposition of second protective film 32a and second protective film 32b on the first end face 2F side relative to first protective film 31a and first protective film 31b, respectively, inhibits oxygen diffusion in second protective films 32a and 32b. Accordingly, oxidation of second protective films 32a and 32b can be inhibited.

Second protective films 32a and 32b may have a polycrystalline structure including at least one of hexagonal crystals or cubic crystals.

Second protective films 32a and 32b each may be a hexagonal crystal in the m-axis orientation relative to first end face 2F.

In this case, addition of scandium having the atomic radius and ion radius greater than the atomic radius and ion radius of aluminum and gallium to second protective films 32a and 32b that are hexagonal crystals causes the lattice constant of each of second protective films 32a and 32b to come closer to the lattice constant of stacked structure 2. This could reduce dangling bonds in stacked structure 2 at the interface between stacked structure 2 and protective film 3, and can reduce crystal defects. The reduction in the dangling bonds as described above can reduce crystal defects in stacked structure 2 in the vicinity of the interface between stacked structure 2 and protective film 3, and can reduce light absorption as well. With this, the reliability of semiconductor light-emitting element 1 can be further increased.

In addition, protective film 3 may include a plurality of stacked films 38a and 38b. Stacked film 38a includes first protective film 31a and second protective film 32a that is in contact with first protective film 31a. Stacked film 38b includes first protective film 31b and second protective film 32b that is in contact with first protective film 31b.

By protective 3 including alternately disposed first protective films having a low refractive index and second protective films having a high refractive index as described above, the reflectance of protective film 3 can be readily controlled.

Protective film 3 includes third protective film 33 that is in contact with first end face 2F, and third protective film 33 may be a silicon nitride film or a silicon oxynitride film.

By protective film 3 including third protective film 33 as described above, the dangling bonds in stacked structure 2 at the interface between stacked structure 2 and protective film 3 could be terminated by third protective film 33. With this, it is possible to increase the adhesion between stacked structure 2 and a protective film (second protective film 32a in the present embodiment) that is adjacent to stacked structure 2 with third protective film 33 interposed therebetween. Moreover, crystal defects in stacked structure 2 in the vicinity of the interface between stacked structure 2 and protective film 3 can be reduced, and light absorption can be reduced as well. Therefore, the reliability of semiconductor light-emitting element 1 can be further increased.

Third protective film 33 may be amorphous.

With this, damage to stacked structure 2 during the film formation of third protective film 33 can be inhibited.

Protective film 3 includes fourth protective film 34 that is a silicon oxide film. First protective films 31a and 31b may be disposed between first end face 2F and fourth protective film 34.

As described, by protective film 3 including fourth protective film 34 having a refractive index less than the refractive index of first protective films 31a and 31b, the reflectance in protective film 3 can be readily controlled.

First protective film 31b may be in contact with fourth protective film 34.

By scandium-added first protective film 31b being in contact with fourth protective film 34 that is a silicon oxide film, silicide (ScSi) could be formed at the interface between these foregoing films. With this, the adhesion between first protective film 31b and fourth protective film 34 can be increased. Therefore, the reliability of semiconductor light-emitting element 1 can be increased.

Fourth protective film 34 may be amorphous.

With this, damage to stacked structure 2 during the film formation of fourth protective film 34 can be inhibited.

### Embodiment 2

A protective film according to Embodiment 2 will be described. The protective film according to the present embodiment is different from protective film 3 according to Embodiment 1 in that the protective film according to the present embodiment does not include second protective films, a third protective film, and a fourth protective film. With reference to FIG. 14, the protective film according to the present embodiment will be hereafter described with emphasis on differences from protective film 3 according to Embodiment 1. FIG. 14 is a cross-sectional view showing a configuration of the protective film according to the present embodiment. FIG. 14 also shows stacked structure 2. FIG. 14 shows a cross-section that is parallel to (i) the resonance direction of light that a semiconductor light-emitting element emits and (ii) the stacked direction of stacked structure 2.

As illustrated in FIG. 14, the protective film according to the present embodiment is first protective film 31a. Stated differently, the protective film according to the present embodiment includes only first protective film 31a.

First protective film 31a has the same configuration as first protective film 31a according to Embodiment 1. First protective film 31a is in contact with first end face 2F of stacked structure 2.

First protective film 31a according to the present embodiment also produces the same advantageous effects as each of the first protective films included in protective film 3 according to Embodiment 1.

Moreover, since the protective film according to the present embodiment only includes first protective film 31a, the protective film according to the present embodiment can be more easily produced than protective film 3 according to Embodiment 1.

### Embodiment 3

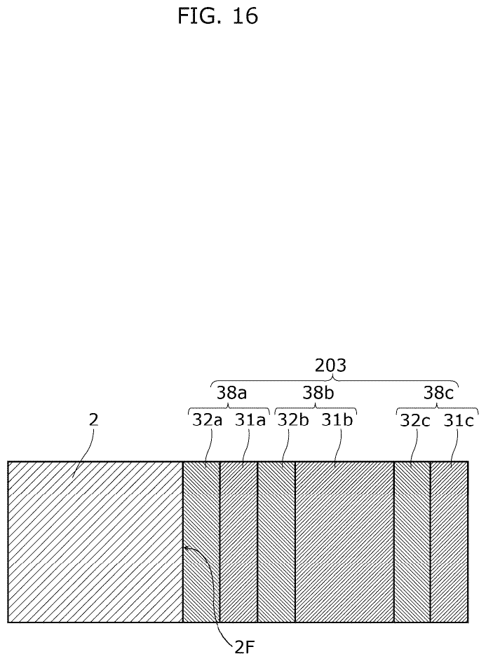

A protective film according to Embodiment 3 will be described. The protective film according to the present embodiment is different from protective film 3 according to Embodiment 1 mainly on the following points: (i) the configuration of second protective films and (ii) no inclusion of a third protective film and a fourth protective film. With reference to FIG. 15, the protective film according to the present embodiment will be hereafter described with emphasis on differences from protective film 3 according to Embodiment 1. FIG. 15 is a cross-sectional view showing a configuration of protective film 103 according to the present embodiment. FIG. 15 also shows stacked structure 2. FIG. 15 shows a cross-section that is parallel to (i) the resonance direction of light that a semiconductor light-emitting element emits and (ii) the stacked direction of stacked structure 2.

As illustrated in FIG. 15, protective film 103 according to the present embodiment includes stacked films 138a, 138b, and 138c. Stacked film 138a includes first protective film 31a and second protective film 132a. Second protective film 132a is disposed between first end face 2F and first protective film 31a and is in contact with first protective film 31a. Stacked film 138b includes first protective film 31b and second protective film 132b. Second protective film 132b is disposed between first end face 2F and first protective film 31b and is in contact with first protective film 31b. Stacked film 138c includes first protective film 31c and second protective film 132c. Second protective film 132c is disposed between first end face 2F and first protective film 31c and is in contact with first protective film 31c.

First protective films 31a and 31b have the same configuration as first protective films 31a and 31b according to Embodiment 1. First protective film 31c is an aluminum oxide film or an aluminum oxynitride film to which scandium is added. The concentration of scandium added to first protective films 31c is less than or equal to 10 at %. First protective film 31c is amorphous or amorphous including a crystalline phase, but may be crystalline.

In the same manner as second protective films 32a and 32b according to Embodiment 1, second protective films 132a, 132b, and 132c each are a crystalline film including an aluminum nitride or an aluminum oxynitride. Second protective films 132a, 132b, and 132c each have a polycrystalline structure including at least one of hexagonal crystals or cubic crystals. Second protective films 132a, 132b, and 132c each may be a hexagonal crystal in the m-axis orientation relative to first end face 2F. Second protective films 132a, 132b, and 132c according to the present embodiment each are an additive-free nitride or an additive-free oxynitride to which no scandium or the like is added.

Each of the first protective films and each of the second protective films included in protective film 103 according to the present embodiment also produce the same advantageous effects as each of the first protective films and each of the second protective films included in protective film 3 according to the present embodiment.

Moreover, by protective film 103 according to the present embodiment including three stacked films 138a, 138b, and 138c, the reflectance of protective film 103 is even more readily controlled. Note that in the present embodiment, protective film 103 includes three stacked films 138a, 138b, and 138c, but protective film 103 may include four or more stacked films.

In addition, since protective film 103 according to the present embodiment only includes first protective films 31a, 31b, and 31c and second protective films 132a, 132b, and 132c, the protective film according to the present embodiment can be more easily produced than protective film 3 according to Embodiment 1.

### Embodiment 4

A protective film according to Embodiment 4 will be described. The protective film according to the present embodiment is different from protective film 103 according to Embodiment 3 in that the configuration of the second protective films according to the present embodiment is different from the second protective films according to Embodiment 3. With reference to FIG. 16, the protective film according to the present embodiment will be hereafter described with emphasis on differences from protective film 103 according to Embodiment 3. FIG. 16 is a cross-sectional view showing a configuration of protective film 203 according to the present embodiment. FIG. 16 also shows stacked structure 2. FIG. 16 shows a cross-section that is parallel to (i) the resonance direction of light that a semiconductor light-emitting element emits and (ii) the stacked direction of stacked structure 2.

As illustrated in FIG. 16, protective film 203 according to the present embodiment includes stacked films 38a, 38b, and 38c. Stacked films 38a and 38b have the same configuration as stacked films 38a and 38b according to Embodiment 1. Stacked film 38c includes first protective film 31c and second protective film 32c. Second protective film 32c is disposed between first end face 2F and first protective film 31c and is in contact with first protective film 31c. First protective film 31c of the present embodiment has the same configuration as first protective film 31c according to Embodiment 3.

Second protective films 32a and 32b have the same configuration as second protective films 32a and 32b according to Embodiment 1. In the same manner as second protective films 32a and 32b according to Embodiment 1, second protective film 32c is a crystalline film including an aluminum nitride or an aluminum oxynitride. In the present embodiment, second protective film 32c is a nitride or an oxynitride to which scandium of 10 at % or less is added.

Protective film 203 including the above-described second protective films 32a, 32b, and 32c also produces the same advantageous effects as protective film 103 according to Embodiment 3.

### Embodiment 5

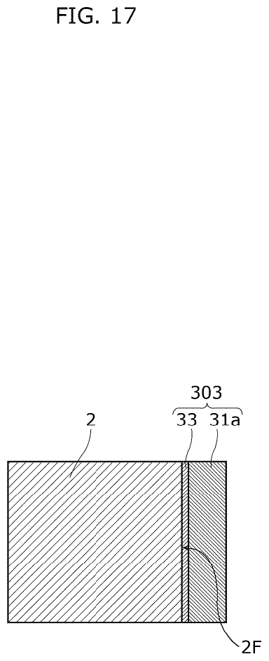

A protective film according to Embodiment 5 will be described. The protective film according to the present embodiment is different from protective film 3 according to Embodiment 1 in that the protective film according to the present embodiment includes only a first protective film and a third protective film. With reference to FIG. 17, the protective film according to the present embodiment will be hereafter described with emphasis on differences from protective film 3 according to Embodiment 1. FIG. 17 is a cross-sectional view showing a configuration of protective film 303 according to the present embodiment. FIG. 17 also shows stacked structure 2. FIG. 17 shows a cross-section that is parallel to (i) the resonance direction of light that a semiconductor light-emitting element emits and (ii) the stacked direction of stacked structure 2.

As illustrated in FIG. 17, protective film 303 according to the present embodiment includes first protective film 31a and third protective film 33.

First protective film 31a has the same configuration as first protective film 31a according to Embodiment 1.

Third protective film 33 has the same configuration as third protective film 33 according to Embodiment 1. In the present embodiment, third protective film 33 is in contact with first protective film 31a.

Protective film 303 according to the present embodiment also produces the same advantageous effects as first protective film 31a and third protective film 33 according to Embodiment 1.

Moreover, since protective film 303 according to the present embodiment only includes two films, namely first protective film 31a and third protective film 33, the protective film according to the present embodiment can be more easily produced than protective film 3 according to Embodiment 1.

### Embodiment 6

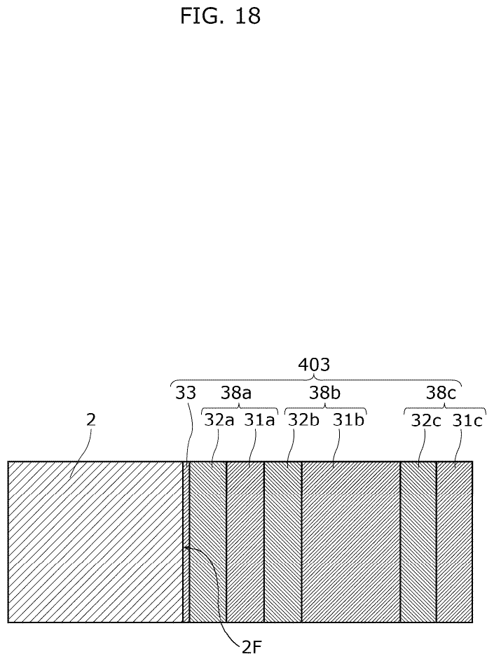

A protective film according to Embodiment 6 will be described. The protective film according to the present embodiment is different from protective film 203 according to Embodiment 4 in that the protective film according to the present embodiment includes a third protective film. With reference to FIG. 18, the protective film according to the present embodiment will be hereafter described with emphasis on differences from protective film 203 according to Embodiment 4. FIG. 18 is a cross-sectional view showing a configuration of protective film 403 according to the present embodiment. FIG. 18 also shows stacked structure 2. FIG. 18 shows a cross-section that is parallel to (i) the resonance direction of light that a semiconductor light-emitting element emits and (ii) the stacked direction of stacked structure 2.

As illustrated in FIG. 18, protective film 403 according to the present embodiment includes stacked films 38a, 38b, and 38c and third protective film 33.

Third protective film 33 has the same configuration as third protective film 33 according to Embodiment 1.

Protective film 403 according to the present embodiment also produces the same advantageous effects as protective film 203 according to Embodiment 4.

Moreover, by including third protective film 33, protective film 403 according to the present embodiment produces the same advantageous effects as third protective film 33 included in protective film 3 according to Embodiment 1.

### Embodiment 7

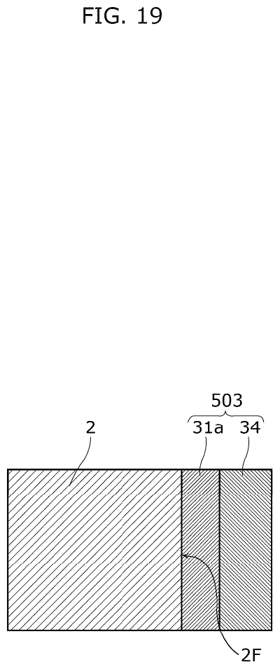

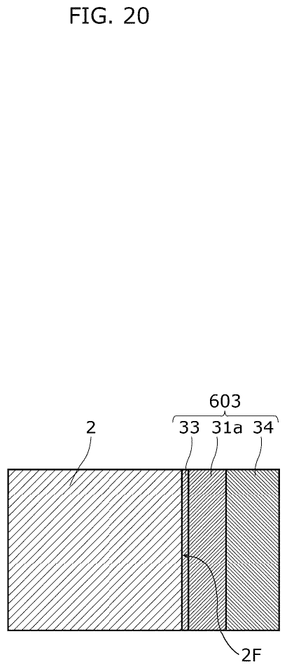

A protective film according to Embodiment 7 will be described. The protective film according to the present embodiment is different from protective film 3 according to Embodiment 1 in that the protective film according to the present embodiment includes only a first protective film and a fourth protective film. With reference to FIG. 19, the protective film according to the present embodiment will be hereafter described with emphasis on differences from protective film 3 according to Embodiment 1. FIG. 19 is a cross-sectional view showing a configuration of protective film 503 according to the present embodiment. FIG. 19 also shows stacked structure 2. FIG. 19 shows a cross-section that is parallel to (i) the resonance direction of light that a semiconductor light-emitting element emits and (ii) the stacked direction of stacked structure 2.

As illustrated in FIG. 19, protective film 503 according to the present embodiment includes first protective film 31a and fourth protective film 34.

First protective film 31a has the same configuration as first protective film 31a according to Embodiment 1. In the present embodiment, first protective film 31a is in contact with first end face 2F.

Fourth protective film 34 has the same configuration as fourth protective film 34 according to Embodiment 1. Fourth protective film 34 is in contact with first protective film 31a.

Protective film 503 according to the present embodiment also produces the same advantageous effects as first protective film 31a and fourth protective film 34 according to Embodiment 1.

Moreover, since protective film 503 according to the present embodiment only includes two films, namely first protective film 31a and fourth protective film 34, the protective film according to the present embodiment can be more easily produced than protective film 3 according to Embodiment 1.

### Embodiment 8

A protective film according to Embodiment 8 will be described. The protective film according to the present embodiment is different from protective film 3 according to Embodiment 1 in that the protective film according to the present embodiment includes only a first protective film, a third protective film, and a fourth protective film. With reference to FIG. 20, the protective film according to the present embodiment will be hereafter described with emphasis on differences from protective film 3 according to Embodiment 1. FIG. 20 is a cross-sectional view showing a configuration of protective film 603 according to the present embodiment. FIG. 20 also shows stacked structure 2. FIG. 20 shows a cross-section that is parallel to (i) the resonance direction of light that a semiconductor light-emitting element emits and (ii) the stacked direction of stacked structure 2.

As illustrated in FIG. 20, protective film 603 according to the present embodiment includes first protective film 31a, third protective film 33, and fourth protective film 34.

First protective film 31a has the same configuration as first protective film 31a according to Embodiment 1. In the present embodiment, first protective film 31a is in contact with third protective film 33 and fourth protective film 34.

Third protective film 33 has the same configuration as third protective film 33 according to Embodiment 1. Third protective film 33 is in contact with first end face 2F and first protective film 31a.

Fourth protective film 34 has the same configuration as fourth protective film 34 according to Embodiment 1. Fourth protective film 34 is in contact with first protective film 31a.

Protective film 603 according to the present embodiment also produces the same advantageous effects as first protective film 31a, third protective film 33, and fourth protective film 34 according to Embodiment 1.

Moreover, since protective film 503 according to the present embodiment only includes three films, namely first protective film 31a, third protective film 33, and fourth protective film 34, the protective film according to the present embodiment can be produced easier than protective film 3 according to Embodiment 1.

### Variations, etc.

Hereinbefore, the semiconductor light-emitting element according to the present disclosure has been described based on the embodiments, but the present disclosure is not limited to the above-described embodiments.

For example, the configuration of stacked structure 2 is not limited to the examples of configurations presented in the above-described embodiments. Stacked structure 2 may be a stacked structure that includes a nitride semiconductor and has first end face 2F and second end face 2R that face each other and form a resonator. Moreover, light that stacked structure 2 emits need not be light in the ultraviolet range.

In addition, although the above-described embodiments have presented examples in which the semiconductor light-emitting element is a semiconductor laser element, the semiconductor light-emitting element is not limited to a semiconductor laser element. For example, the semiconductor light-emitting element may be a superluminescent diode.

Furthermore, although the protective film included in the semiconductor light-emitting element according to the above-described embodiments include a first protective film, the protective film may include only a second protective film without including the first protective film. In other words, the semiconductor light-emitting element according to the present disclosure may include: a stacked structure including a nitride semiconductor and having a first end face and a second end face that face each other and form a resonator; and a protective film provided on the first end face. In the semiconductor light-emitting element according to the present disclosure, the protective film may include a second protective film, and the second protective film may be a crystalline film including an aluminum oxide film or an aluminum oxynitride film to which scandium is added. In the semiconductor light-emitting element as described above, oxygen could be trapped in the second protective film that is a crystalline film. With this, oxidation of the stacked structure can be inhibited, and thus the reliability of the semiconductor light-emitting element can be increased.

Moreover, although stacked structure 2 included in the semiconductor light-emitting element according to the above-described embodiments includes a nitride semiconductor, the stacked structure according to the present disclosure need not necessarily include a nitride semiconductor. For example, the stacked structure may include an arsenide semiconductor such as Al_{X1}Ga_{X2}In_{X3}As (where 0≤X1≤1, 0≤X2≤1, 0≤X3≤1, and X1+X2+X3=1) or a phosphide semiconductor such as Al_{Y1}Ga_{Y2}In_{Y3}P (where 0≤Y1≤1, 0≤Y2≤1, 0≤Y3≤1, and Y1+Y2+Y3=1). For example, the semiconductor light-emitting element according to the present disclosure may include: a stacked structure including an arsenide semiconductor or a phosphide semiconductor and having a first end face and a second end face that face each other and form a resonator; and a protective film provided on the first end face. In the semiconductor light-emitting element according to the present disclosure, the protective film may include a first protective film, and the first protective film may be an aluminum oxide film to which scandium is added. The above-described first protective film according to the present embodiment produces the same advantageous effects as the first protective films according to the above-described embodiments. For example, the protective film may include a fourth protective film that is a silicon oxide film, and the first protective film may be disposed between the first end face and the fourth protective film. As described, by the protective film including the fourth protective film having a refractive index less than the refractive index of the first protective film, the reflectance in the protective film can be readily controlled. For example, the first protective film may be in contact with the fourth protective film. As described above, by the first protective film to which scandium is added being in contact with the fourth protective film that is a silicon oxide film, silicide (ScSi) could be formed at the interface between these foregoing films. With this, the adhesion between the first protective film and the fourth protective film can be increased. Therefore, the reliability of the semiconductor light-emitting element can be increased. For example, the fourth protective film may be amorphous. With this, damage to the stacked structure during the film formation of the fourth protective film can be inhibited.

In addition, in the above-described embodiment, the protective film is disposed on each of first end face 2F and second end face 2R, but the protective film may be disposed on at least one of first end face 2F or second end face 2R. Furthermore, each of the protective films disposed on first end face 2F in the above-described embodiments may be disposed on second end face 2R.

Those skilled in the art will readily appreciate that various modifications may be made in these embodiments and that other embodiments may be obtained by optionally combining the elements and functions of the embodiments without materially departing from the novel teachings and advantages of the present disclosure. Accordingly, all such modifications and other embodiments are included in the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The semiconductor light-emitting element according to the present disclosure is particularly useful for external resonance-type semiconductor light-emitting elements that need to control the end face reflectance of high-power semiconductor light sources such as light sources for laser machining, high-power light sources such as light sources for laser direct imaging (LDI), and light sources for direct diode laser (DDL).

1. A semiconductor light-emitting element comprising:
a stacked structure including a semiconductor, the stacked structure having a first end face and a second end face facing each other and forming a resonator; and
a protective film disposed on the first end face, wherein
the protective film includes a first protective film, and
the first protective film is an aluminum oxide film or an aluminum oxynitride film to which scandium is added.

2. The semiconductor light-emitting element according to claim 1, wherein
the first protective film is amorphous or amorphous including a crystalline phase.

3. The semiconductor light-emitting element according to claim 1, wherein
a concentration of the scandium added to the first protective film is less than or equal to 10 atomic %.

4. The semiconductor light-emitting element according to claim 1, wherein
the protective film includes a second protective film disposed between the first end face and the first protective film, and
the second protective film is a crystalline film including an aluminum nitride or an aluminum oxynitride to which scandium is added.

5. The semiconductor light-emitting element according to claim 4, wherein
a concentration of the scandium added to the second protective film is less than or equal to 10 atomic %.

6. The semiconductor light-emitting element according to claim 4, wherein
the second protective film has a polycrystalline structure including at least one of hexagonal crystals or cubic crystals.

7. The semiconductor light-emitting element according to claim 4, wherein
the second protective film is a hexagonal crystal in an m-axis orientation relative to the first end face.

8. The semiconductor light-emitting element according to claim 4, wherein
the protective film includes a plurality of stacked films, and
each of the plurality of stacked films includes the first protective film and the second protective film that is in contact with the first protective film.

9. The semiconductor light-emitting element according to claim 1, wherein
the protective film includes a third protective film that is in contact with the first end face, and
the third protective film is a silicon nitride film or a silicon oxynitride film.

10. The semiconductor light-emitting element according to claim 9, wherein
the third protective film is amorphous.

11. The semiconductor light-emitting element according to claim 1, wherein
the protective film includes a fourth protective film that is a silicon oxide film, and
the first protective film is disposed between the first end face and the fourth protective film.

12. The semiconductor light-emitting element according to claim 11, wherein
the first protective film is in contact with the fourth protective film.

13. The semiconductor light-emitting element according to claim 11, wherein
the fourth protective film is amorphous.

14. The semiconductor light-emitting element according to claim 1, wherein
the protective film includes a light-induced crystallization region that has been crystallized due to light,
the light-induced crystallization region includes at least a portion of a region through which light emitted by the semiconductor light-emitting element propagates, and
in a direction perpendicular to a propagation direction of the light, a dimension of the light-induced crystallization region in the first protective film takes on a minimum value at a position between both interfaces of the first protective film.

15. The semiconductor light-emitting element according to claim 4, wherein
the protective film includes an inner protective film that is disposed between the first end face and the second protective film,
the inner protective film is an aluminum oxide film or an aluminum oxynitride film to which scandium is added,
the protective film includes a light-induced crystallization region including at least a portion of a region through which light emitted by the semiconductor light-emitting element propagates, and
in a direction perpendicular to a propagation direction of the light, a dimension of the light-induced crystallization region in the inner protective film is greater than a dimension of the light-induced crystallization region in the first protective film.
